(19) United States
(12) Patent Application Publication
(10) Pub. No.: US 2004/0012388 A1
(43) Pub. Date: Jan. 22, 2004

(54) Method and apparatus for measuring magnetic field strengths

(76) Inventor: Erik Horsdal Pedersen, Aarhus (DK)

Correspondence Address: James C Wray, Suite 300, 1493 Chain Bridge Road, McLean, VA, 22101, US

(21) Appl. No.: 10/380,384

(22) PCT Filed: Sep. 11, 2001
(86) PCT No.: PCT/DK01/00587

(30) Foreign Application Priority Data
Sep. 14, 2000 (DK) PA 2000-01363

(51) Int. Cl. G01R 33/02

(52) U.S. Cl. 324/244.1

(57) ABSTRACT

The invention is a method and apparatus for measuring the strengths of magnetic fields directly in units of frequency of a rotating or oscillating electric field utilising a novel resonance phenomenon called atomic pseudo-spin resonance, ApSR. The ratio of field to frequency is 2m/e, where m and e are the reduced electron mass and the elementary charge, respectively. The magnetic field-strength is thus tied directly to the best physical standard known at present, the frequency of atomic clocks, and the tie is a fundamental constant of nature known with exceedingly good precision.

### 1. BACKGROUND OF THE INVENTION

Natural magnetic fields surround the Earth and penetrate deep into its interiour regions. The main sources of these fields are electric currents in the liquid core of the planet and in the ionized regions of its atmosphere, but locally, in the Earths' crust and on the surface, specific sources in the form of nearby minerals of varying magnetic properties can also be important. There is even a weak, but nevertheless detectable, field-component on Earth from the current of the solar wind. The atmospheric magnetic field is important for the structure and physics of the atmosphere, and is therefore essential for life on Earth. Also, navigation on Earth and in space close to Earth still relies strongly on the natural magnetic field. The solar magnetic field powered by the solar wind extends throughout the huge region of the heliosphere, and it may very well prove to have direct and important consequences for the global climate on Earth including the overall heating of the atmosphere currently attributed to the greenhouse effect [1]. The natural magnetic fields are variable, and reflect the changing strengths of their sources. The reasons for these changes are normally not known. The natural magnetic fields are thus important in the continuing quest for understanding the interiour of our planet, its atmosphere, and its climate, and they are also essential in prospecting for minerals, in particular ferromagnetic substances.

Artificial magnetic fields are used in prospecting for non-ferromagnetic minerals like oil. These minerals can be detected by the method of nuclear magnetic resonance, NMR, through their responce to strong, time-dependent magnetic fields. The responce is specific to the particular chemical constitution of the mineral. The NMR technique is also used extensively in organic chemistry to determine molecular structure, and in the medical sector, where sophisticated MR-scanners with carefully designed and controlled, inhomogeneous magnetic fields have become very important diagostic tools.

The widespread interests both in natural and artificial magnetic fields underpins the scientific and commercial need for a continuing refinement of the precision and the stability of the techniques at our disposal for measuring magnetic fields.

A number of devices for the measurement of magnetic fields of various strengths are in current use and/or under development. These include rotating coils, Hall elements, flux gates, SQUIDs (Superconducting QUantum Interference Device), and NMR-probes (Nuclear Magnetic Resonance).

In rotating coils the electromotive force induced in the windings is proportional to the strength of the magnetic field. In a Hall-element carrying an electric current the Lorentz force on the charge-carriers from an external magnetic field leads to a voltage proportional to the field strength. Flux gates explore the saturation characteristics of ferromagnetic materials to detect very small magnetic fields. A SQUID uses two Josephson junctions in a superconducting current loop to measure the magnetic flux through the loop in terms of the fundamental quantum unit of flux. The responce of each of these devices depends on system-specific parameters and therefore needs calibration.

The NMR-technique is in some respects similar to the Atomic pseudo Spin Resonance technique, ApSR, to be described in this report. The NMR was developed for the measurement of unknown nuclear magnetic moments and accomplished this by detecting the resonant response of the magnetic moments to an oscillating magnetic field in the presence of a strong DC magnetic field of known strength. The magnetic moment is directly proportional to the resonance frequency and inversely proportional to the DC field-strength. Of these three parameters, one can be measured precisely in absolute units, only if the other two are known, which is a disadvantage of the method. When the technique is reversed and used as a device for detecting strong magnetic fields it is indeed very precise and reproducible, however, absolute determination of the field strength requires prior knowledge of the nuclear magnetic moment.

It is an object of the invention to provide a method and apparatus for measuring magnetic field strengths not only in relative but in absolute units without the necessity of continuous calibration.

### 2. DESCRIPTION OF THE INVENTION

According to the invention this object is achieved by a method for measuring the strength of a magnetic field wherein said strength of said magnetic field is related to the frequency of a rotating or oscillating electric field and said frequency of said rotating or oscillating field is determined.

The invention is based on a new resonance phenomenon, which is called atomic pseudo-spin resonance, ApSR. It takes advantage of a particular pseudo-spin vector defined for hydrogenic atomic systems. When compared to the well-known NMR-technique, the ApSR uses the pseudo-spin vector in place of the magnetic moment, and an oscillating electric field in place of an oscillating magnetic field. It allows a magnetic field-strength to be measured directly in units of frequency, . The ratio of resonance frequency to magnetic field-strength equals e/2m, where e and m are the elementary charge and the reduced electron mass, respectively. This is the Bohr magneton divided by Plancks constant. The magnetic field-strength is thus directly proportional to the best physical standard known at present, the frequency of atomic clocks, and the constant of proportionality depends only on fundamental constants of nature known with exceedingly good precision. The ApSR is free of system-dependent parameters and does not need calibration. It covers a range of relatively weak field strength extending from the strength of the Earths' magnetic field to 10³ times this value, 0.5-500 Gauss

2.1 Principle of the Invention

When motion is described by reference to a non-inertial coordinate system the law of inertia is no longer valid, and the motion is influenced by fictitious forces. These are the centrifugal and the Coriolis forces [2]. The total fictitious force acting on a swiftly-moving particle in a slowly rotating coordinate system has the same form as the Lorentz force exerted on a charged particle moving in a magnetic field [3]. This equivalence of forces combined with detection methods to determine when a given magnetic force is exactly balanced by a fictitious force is the principle of the invention.

In the next three subsections we discuss the equivalence of forces, Sec. 2.2, and three methods for detecting the balance point. The near-adiabatic transformation method, Sec. 2.3, has already been implemented and two ultra-sensitive quantum interference methods, Sec. 2.4, are proposed.

2.2 Equivalence of Forces

Consider the motion of a classical electron with electric charge, −e, and mass, m, under the simultaneous influence of a homogeneous magnetostatic field, B, and a fixed spherically symmetric electrostatic potential, V(r), where r is the distance from the symmetry point of the potential to the particle. The Lagrange function, which governs the motion, has the following form in an inertial reference system with the origin at the symmetry point [3]

$$L = \frac{1}{2} m {\vec{v}}^{2} + e V ( r ) - e \vec{v} \cdot \vec{A} with \vec{A} = \frac{1}{2} \vec{B} \times \vec{r} , \qquad ( 1 )$$

where v is the velocity of the particle and A the vector potential of the magnetic field, B=∇>A.

Consider the same motion in a rotating coordinate system whose origin coincides with the origin of the inertial system and whose rotation is given by the rotation vector Q. The position and velocity vectors with reference to the rotating system are r′ and v′, respectively. In terms of these quantities the velocity and the vector potential in the inertial system are given by v=v′+Ω×r′ and A=1/2B×r′, respectively. The Lagrange function may thus be written

$$L = \frac{1}{2} {m ( \vec{v} + \vec{Ω} \times {\vec{r}}^{′} )}^{2} + e V ( {r}^{′} ) - e ( {\vec{v}}^{′} + \vec{Ω} \times {\vec{r}}^{′} ) \cdot \frac{1}{2} \vec{B} \times {\vec{r}}^{′} \qquad ( 2 )$$

where we have also used r=r′.

We now assume that the magnetic field is weak and the rotation slow. This allows us to simplify Eq. (2) by looking apart from terms that are small to the second power. The approximation is well justified in the present context as discussed in Sec. 4.8 below, and it leads to the expression

$$L = \frac{1}{2} m {{\vec{v}}^{′}}^{2} + e V ( {r}^{′} ) - \frac{e}{2} {\vec{v}}^{′} \cdot ( \vec{B} - \frac{2 m}{e} \vec{Ω} ) \times {\vec{r}}^{′} . \qquad ( 3 )$$

The fictitious forces thus combine to act on the charged particle like a homogeneous magnetic field of strength −(2m/e)Ω, so the motion in the rotating system is identical to the motion in an inertial system with an effective magnetic field

$${\vec{B}}_{eff} = \vec{B} - \frac{2 m}{e} \vec{Ω} . \qquad ( 4 )$$

The fictitious and the true magnetic forces balance each other when

$$\vec{B} = \frac{2 m}{e} \vec{Ω} . \qquad ( 5 )$$

In quantum mechanics the problem corresponding to Eq. (3) is described by the Hamiltonean

$$H = \frac{{{\vec{p}}^{′}}^{2}}{2 m} - e V ( {r}^{′} ) + \frac{e}{2 m} \vec{l} \cdot ( \vec{B} - \frac{2 m}{e} \vec{Ω} ) + \frac{e}{m} \vec{s} \cdot \vec{B} , \qquad ( 6 )$$

where p′ is the momentum operator, I the orbital angular momentum, and s the quantum mechanical spin angular momentum. We bring this expression for later reference. For an electron the charge-to-mass ratio is e/m=1.758820174×10⁻¹¹ C/kg [4]. It leads to the conversion factor B/f2π·2m/e=0.7144772843 Gauss/MHz, where f=Ω/2π is the rotation frequency. 2.3 Near-Adiabatic Transformation Method

Imagine now that the electron is bound in the spherically symmetric potential of a singly-charged ion. The two form a neutral atom. Imagine further that the electronic motion is influenced not only by a homogeneous magnetostatic field, B, as in the previous paragraph, Sec. 2.2, but also by a homogeneous electric field, E, which is perpendicular to B, rotates about B at the constant angular frequency Ω, and varies in absolute magnitude as a function of time. An illustration of the field configuration is given in FIG. 1. The motion of the electron in this time-dependent field configuration presents a quite complicated dynamical problem. However, in a reference system rotating about B at the angular frequency Ω, the electric field points in a fixed direction and so does the magnetic field. The price to be paid for this simplification is the appearence, as shown in Sec. 2.2, of a fictitious force. In the present context this is not a drawback but rather an asset because it allows, as we shall see, the magnetic field to be measured accurately in frequency units.

In the rotating reference system we are dealing with the motion of an electron under the influence of a spherically symmetric potential, a time-dependent but non-rotating electric field, and an effective magnetostatic field perpendicular to the electric field and given by Eq. (4). This is still a complicated problem, but it has been thoroughly analyzed for weak fields and exact solutions exist when the ionic potential is purely Coulombic [5]. The solutions are approximately correct even when the ionic potential has a non-hydrogenic core if only highly-excited, one-electron states are considered. Such states are called Rydberg states. In the following sections we will concentrate on Rydberg states and discuss the electronic motion within the degenerate Hilbert space of a single atomic shell with principal quantum number n. An electron in a Rydberg state will be referred to as a Rydberg electron and the whole atom as a Rydberg atom.

The experimental data to be presented were obtained for n=25. The dimension of the Hilbert space is n²=625.

A technique combining pulsed laser excitation of a specific initial Rydberg state with subsequent adiabatic transformation of that specific state by external, time-dependent fields may be used to produce Rydberg electrons which all move about their respective ionic cores in circular orbits of given size and orientation [6]. In a spherical representation the circular wavefunction is |n,l,m [symbol] =|n,n−1,n−1 [symbol] when quantized in the direction of the constant magnetic field to be measured. This circular Rydberg state is the starting point of the near-adiabatic transformation method. The rotating electric field has an amplitude, E(t), which may be designed to vary as follows. It is extremely small during the formation of the circular state but it afterwards increases and settles at a constant value before it returns to the initial low value. The circular atoms are thus exposed to a pulsed, rotating electric field parallel to the plane of the circular orbits.

We now discuss, in qualitative terms, the effect on a circular state of the electric field E(t). The rotating coordinate system will be used, and to aid the discussion, FIGS. 2a, 2b and 2c show schematically for three representative values of E/B 21, 21′, and 21″ manifolds of quasi-stationary energy levels 22, 22′, and 22″ and classical ellipses 23, 23′, and 23″. The laser excitation and the initial adiabatic transformation prepares the quantum system in a circular state, 23. The position of this system in the energy spectrum is indicated by a dot 24 in FIG. 2a.

If E increases slowly, the circular state 23 is transformed adiabatically through a full range of elliptic states 23′ with major axis parallel to E and orbital plane perpendicular to B, until it is finally almost a pure, linear Stark state 23″. The position of the intermediate elliptic state 23′ is indicated by the dot 24′, and the position of the final linear state by the dot 24″.

If the subsequent decrease of E is also slow then the system will return to the circular state as if the field had not been applied at all. However, if the rate-of-change of E is rapid, the wavefunction does not have sufficient time to fully adjust to the changing external forces, and transitions to other quasi-stationary energy levels will take place with appreciable probability. The appropriate transition probabilities are most easily calculated when the n² Rydberg states of the shell are described by the projections, mⱼ₁ and mⱼ₂, onto specific directions of two independent pseudo-spins, j₁ and j₂ [5]. The pseudo-spins have constant magnitude, j₁=j₂=j=(n−1)/2, given by n, and mⱼ₁ and mⱼ₂ can take any one of the n values −j, −j+1, . . . , j−1,j. When transitions take place the dynamics is said to be non-adiabatic. A range of states, that might be populated in a non-adiabatic transformation, is indicated in FIG. 2c by several crosses 25 [5,7]. Transition probabilities are large when the Larmor frequency of the pseudo-spins, (e/2m)B, resonates with the rotation frequency, Ω. This is the reason for the chosen name of the resonance phenomenon, Atomic pseudo Spin Resonance, ApSR.

In order to make the discussion a bit more quantitative it is useful to introduce the effective Larmor frequency, ω_{L}=(e/2m)B_{eff}, and the Stark frequency, ω_{S}=(3nh/4πme)E, in the rotating frame. The quantity h is Plancks constant. The Stark-Zeeman splitting of the energy levels, ω, and the eccentricity of the elliptic states, ε, are then given by [8]

$$ω = {( {ω}_{L}^{2} + {ω}_{S}^{2} )}^{1 / 2} and ϵ = {ω}_{S} / ω , \qquad ( 7 )$$

respectively, and the criterion for adiabatic evolution is [6,7,8]

(dε/dt)/(1−ε²)^{1/2}<<ω, (8)

which in mathematical terms expresses the requirement that the rate-of-change of the eccentricity, dε/dt, must be small compared to the splitting of the energy spectrum, ω. For a constant magnetic field, dω_{L}/dt=0, the expression takes the form

$$\vert \frac{ⅆ {ω}_{S}}{ⅆ t} \vert << {( {ω}_{L}^{2} + {ω}_{S}^{2} )}^{3 / 2} / {ω}_{L} . \qquad ( 9 )$$

This criterion looks quite simple but is actually difficult to discuss in general terms. At this point in the discussion we just state that it may be violated at |ω_{L}|-values smaller then a certain critical value, and that the interval of violating ω_{L} can be quite narrow.

The effect of having non-adiabatic electronic evolution is easily detectable by the method of selective field ionization, SFI, to be discussed later in Sec. 4.4 of the detailed description of the invention. This constitutes the desired method for sensitively determining when B_{eff} approches zero, i.e. for precisely balancing the true magnetic field, B, against the fictitious field, (2m/e)Ω. The Rydberg atoms thus act as sensitive probes that tell when B=(2m/e)Ω is exactly satisfied.

2.4 Quantum Interference Methods

The detection of the ApSR may also be done by quantum interference methods. The proposed techniques are analogues to the Rabi and Ramsey [9] methods developed more than 50 years ago for the precise measurement of nuclear moments and later adapted for the description of optical resonances in two-level atoms [10].

In the previous section it was assumed that the rotating electric field was turned on and off sufficiently slowly that the Rydberg atoms propagate adiabatically through quasi-stationary states except for very small values of B_{eff}. In the quantum interference methods to be discussed it is assumed that the rotating field is turned on and off suddenly. Since the Rydberg atoms are unable to follow the sudden switching, they are brought into non-stationary states that develop non-trivially in time. The Rabi method uses one field pulse, whereas the Ramsey method uses two pulses with a given period in between. While the near-adiabatic transformation method leads to a simple resonance curve in the form of a dip in the probability for adiabatic transformation, both the Rabi and the Ramsey methods lead to rich oscillatory structures which allow the frequency of the resonance to be determined with very high precision.

In order to elucidate the connection between the nuclear moments of the Rabi or Ramsey methods and the present Rydberg states we give explicit expressions for the independent pseudo-spins that describe these states. They are j₁=1/2(l+a) and j₂=1/2(l−a), where l and a are the conserved orbital angular momentum and Runge-Lenz vectors, respectively. We also need the combined Stark-Zeeman fields defined by ω₁=ω_{L}+ω_{S} and ω₁=ω_{L}−ω_{S}. In terms of these quantities the Hamiltonean of the Rydberg atoms in the external fields can be written as

H=Hₐ−\vec{j}₁·\vec{ω}₁−\vec{j}₂·\vec{ω}₂ (10)

where Hₐ is the atomic Hamiltonean [5,8]. The expression results from Eq. (6) with the following steps. A term, r′·E, must be added to represent the Stark energy, the Pauli operator replacement, r′→−3n/2·a, valid for a single shell n is used, and the two spin directions of the electron are treated separately because the weak spin-orbit coupling of Rydberg states is broken by the B-field. Eq. (10) is formally the Hamiltonean of two independent magnetic dipole moments, j₁ and j₂, in two different magnetic fields, ω₁ and ω₂. The Majorana theorem allows this pseudo-spin problem to be reduced to two independent spin-1/2 problems [9]. The two spin-1/2 problems are identical for orthogonal fields. For the case of sudden switching the spin-1/2 problem was solved by Rabi and Ramsey who gave analytic expressions for the probability of the spin-flip, 1/2→−1/2.

The Rabi probability is

$${P}_{Rabi} = {sin}^{2} Θ \cdot {sin}^{2} ( \frac{{ω}_{R} \cdot τ}{2} ) , \qquad ( 11 )$$

where τ is the duration of the pulse, ω_{R}=(ω_{L}²+ω_{S}²)^{1/2} is the Stark-Zeeman splitting, also called the Rabi frequency, and sin²Θ=(ω_{S}/ω_{R})² is a Lorentzian envelope function associated with the eccentricity parameter, Eq. (7).

The Ramsey probability is

$${P}_{Ramsey} = 4 {{P}_{Rabi} ( cos ( \frac{{ω}_{L} T}{2} ) cos ( \frac{{ω}_{R} τ}{2} ) - cos Θsin ( \frac{{ω}_{L} T}{2} ) sin ( \frac{{ω}_{R} τ}{2} ) )}^{2} , \qquad ( 12 )$$

where τ is the duration of each of the two pulses, T the period between the pulses, and cosΘ=ω_{L}/ω_{R}.

Each probability is a symmetrical function of ω_{L}, and the Rabi expression for a single pulse of duration 2τ is obtained from Eq. (12) when T=0.

Elliptic states have maximum spin projections, mⱼ₁=±(n−1)/2 and mⱼ₂=±(n−1)/2. The n−1 spin-1/2 components of each pseudo-spin thus point in the same direction. The orientation of the elliptic states relative to the fields are given by the signs of mⱼ₁ and mⱼ₂, and the eccentricity by the angle between j₁ and j₂. After the Rabi or Ramsey mixings, the chosen circular state |n,n−1,n−1 [symbol] is left unchanged if none of the 2n−2 pseudo-spins flip. This happens with a probability P₊=(1−P_{R})²ⁿ⁻², where P_{R} is either the Rabi or the Ramsey frequency. The circular state may also be transformed to the circular state of opposite angular momentum |n, n−1, −n+1 [symbol] . This happens if all the pseudospins flip, and is described by the probability P₋=P_{R}²ⁿ⁻². The total probability for finally being in any of the two circular states after the switching is P=P₊+P₋. This probability can be measured by the SFI method, as described below in Sec. 4.4. Theoretical values of P as a function of the rotation frequency f are shown in FIGS. 3, 4, and 5 where the frequency f is in units of 30 MNz.

The Rabi curves FIG. 3 which give the probability that the Rydberg atom is left in a circular state were calculated for B=21.4 Gauss, which corresponds to f₀=30 MHz, ω_{S}/2πf₀=0.05, and π=4 μs. The peaks correspond to P_{Rabi}=0 or P₊=1. The term P₋is always close to zero. The sensitivity to experimental imperfections in the form of, for example, jitter in the timing pulses are indicated by curves 31, 32, 33, 34, where the curves 32, 33, 34 other than the uppermost curve 31 are averaged over gaussian distributions of the pulse duration r,

$$⟨ {P}_{R} ⟩ = \frac{1}{\sqrt{2 πσ}} \int {P}_{R} ( {τ}^{′} ) exp ( - \frac{{( {τ}^{′} - τ )}^{2}}{2 {σ}^{2}} ) ⅆ {τ}^{′} \qquad ( 13 )$$

with σ/τ=0.5%, 1.0%, and 1.5%, respectively. The Rabi oscillations are seen to be relatively insensitive to small variations of the argument ω_{R}·τ. The variations can be due to jitter in the timing pulses but it can also be due to noise in the electric field. It is also clear from FIG. 3 that only the central peak will be seen if magnetic field inhomogeneities are larger than about 1%, corresponding to the separation of the side oscillations.

The Ramsey curves 41, 42, 43, 44 in FIG. 4 and 51, 52, 53, 54 in FIG. 5 have T=8 μs and the same values of B, ω_{S}/2πf₀, and r as the Rabi curves of FIG. 3. The curves 41, 42, 43, 44 were obtained for fixed T, and the lower curves 42, 43, 44 show the effect of averaging τ with σ/τ=0.5%, 1.0%, and 1.5%. The curves 51, 52, 53, 54 were obtained for fixed τ, and the lower curves 52, 53, 54 show the effect of averaging T with σ/T=1%, 2%, and 3%.

Just like the Rabi oscillations, the Ramsey fringes are relatively insensitive to small variations of the arguments on which they depend, so that, for example, a time jitter only has limited influence on the appearance of the spectrum. However, the fringes will be resolved only if field inhomogeneities are less than 0.1%. Note, that the relatively wide fringes near 0.956 and 0.970 in FIG. 4 and S are remnants of Rabi oscillations.

The Rabi oscillations depend on the effective magnetic field strength, Buffs in the rotating frame through the combined electric and magnetic fields, ω_{R}. The period of the oscillations as a function of frequency therefore vary with detuning relative to the resonance frequency f₀. This is seen clearly in FIG. 3. Since the period depends not only on B_{eff} but also on the electric field, measuring the period does not give direct information on B_{eff}. However, the oscillations are symmetrically distributed around the frequency f₀ for which B_{eff}=0, and they therefore assist in determining the precise value of f₀.

The Ramsey fringes, which originate from the sine and cosine functions of ω_{L}T/2 in Eq. (12) single out the frequencies, ω_{L}, at which the factor multiplying P_{Rabi} in Eq. (12) approaches zero. These frequencies depend only on B_{eff} and T and therefore give extra information on the exact value of B.

From the above, it is understood that magnetic fields can be related to frequencies of rotating electric fields.

Aspects of the invention will become more apparent from the following detailed description in conjunction with the drawings.

### 3. BRIEF DESCRIPTION OF THE DRAWINGS

FIG. 1 is a diagram of the electric, E, and magnetic, B, fields. The spiral-shaped curve marks the end-point of E(t) as it increases from zero while rotating about B at the frequency Ω.

FIG. 2 shows quasi-stationary Stark-Zeeman energy levels and elliptic states of Rydberg atoms.

FIG. 3 shows Rabi probabilities P=(1−P_{Rabi})²ⁿ⁻² as a function of the rotation frequency of the rotating electric field in units of 30 MHz, τ=4 μsec, τ averaged with a time jitter of σ/τ=0, σ/τ=±0.5%, σ/τ=±1%, and σ/τ=±1.5%.

FIG. 4 shows Ramsey probabilities P=(1−P_{Ramsey})²ⁿ⁻² as a function of the rotation frequency of the rotating electric field in units of 30 MHz, T=8 μsec, τ=4 μsec, τ averaged with a time jitter of σ/τ=0, σ/τ=±0.5%, σ/τ=±1%, and σ/τ=±1.5%.

FIG. 5 shows Ramsey probabilities P=(1−P_{Ramsey})²ⁿ⁻² as a function of the rotation frequency of the rotating electric field in units of 30 MHz for fixed τ. T=8 μsec, T=4 μsec, T averaged with a time jitter of σ/T=0, σ/T=±1%, σ/T=±2%, and σ/T=±3%.

FIG. 6 is a schematic diagram of the experimental arrangement showing the oven for the vertical beam of Li atoms, the bars of the Stark cage, the laser beams, the SFI-plates, and the detector for Li⁺ions. A vertical magnetic field of adjustable magnitude is produced by a solenoid, not shown, whose symmetry axis coincides with the Li beam.

FIG. 8 is an energy-level diagram illustrating adiabatic and diabatic field ionization.

FIG. 9 shows SFI spectra measured on and off resonance.

FIG. 10 illustrates the adiabatic parameter, R, as a function of current, I, for f=30 MHz.

FIG. 11 illustrates the adiabatic parameter, R, as a function of current, I, for f=50 MHz.

FIG. 12 illustrates the adiabatic parameter, R, as a function of current, I, for several values of f near 30 MHz.

FIG. 13 is a diagram of the current at resonance, I₀, as a function of frequency, f.

### 4. DETAILED DESCRIPTION OF THE INVENTION

Under normal circumstances a DC magnetic field is given and one would like to measure the strength of that field. With the ApSR discussed above this would imply tuning the frequency of the electric field into resonance. Alternatively, one could be interested in obtaining a predetermined field-strength in an electromagnet by tuning the magnetic field into resonance with the appropriate frequency. The following is a description of a pilot experiment performed to demonstrate that the ApSR is a real physical effect. For reasons, which will become clear, this goal was most conveniently achieve by using the second alternative mentioned above. Consequently, in the experiments to be described the magnetic field-strength was tuned into resonance at a fixed frequency.

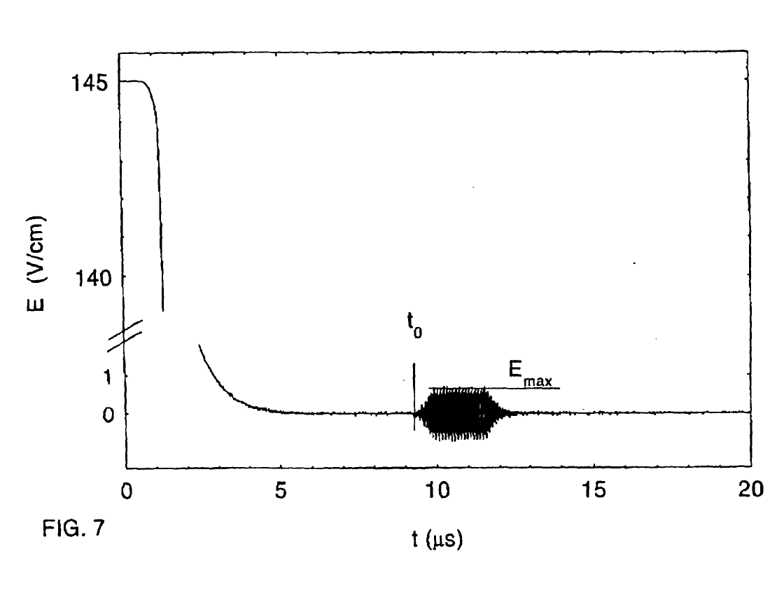

The experimental arrangement used in the pilot experiment is shown in FIG. 6. An oven 61 produces a vertical beam 62 of atoms to be used as probes. In a so-called Stark cage 63 the atoms are first prepared as probes and subsequently used as such. In a detection region 64 the atoms are analyzed by the technique of selective field ionization (SFI). The name “Stark cage” is used because an electric field inside a cage-like structure induces a Stark splitting of atomic energy levels. A vertical magnetic field is formed by a current running through the windings of a solenoid (not shown) which embraces the Stark cage and the SFI region.

4.1 The Atomic Probes—Production and Preparation

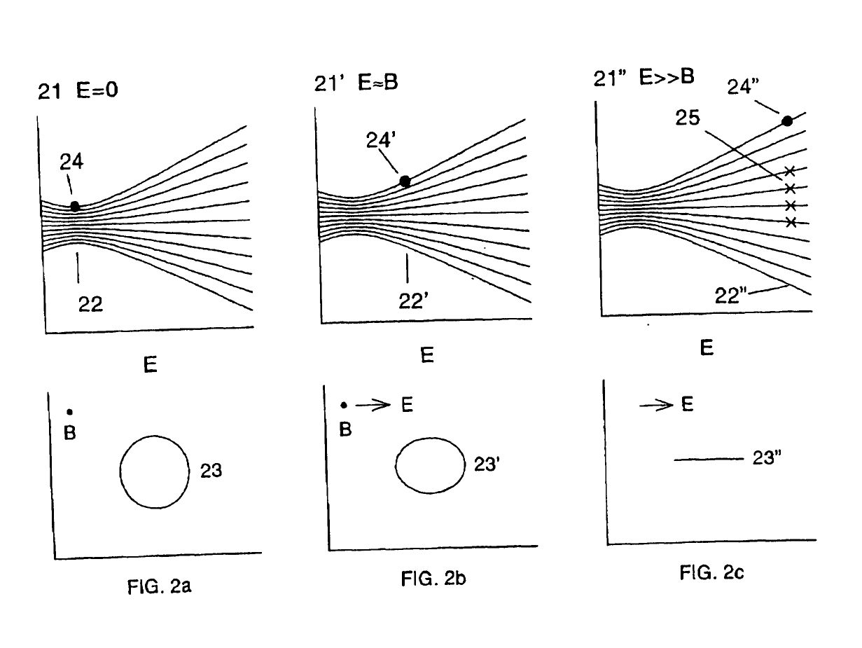

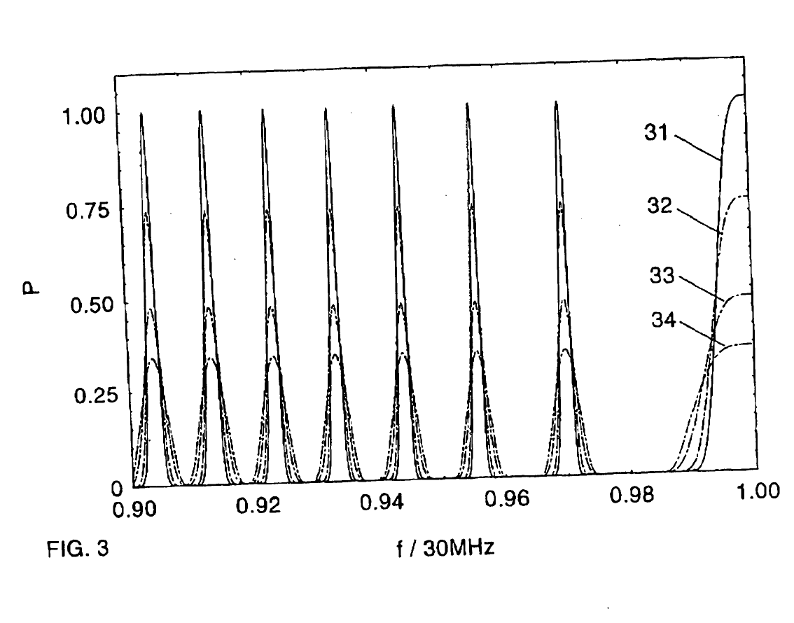

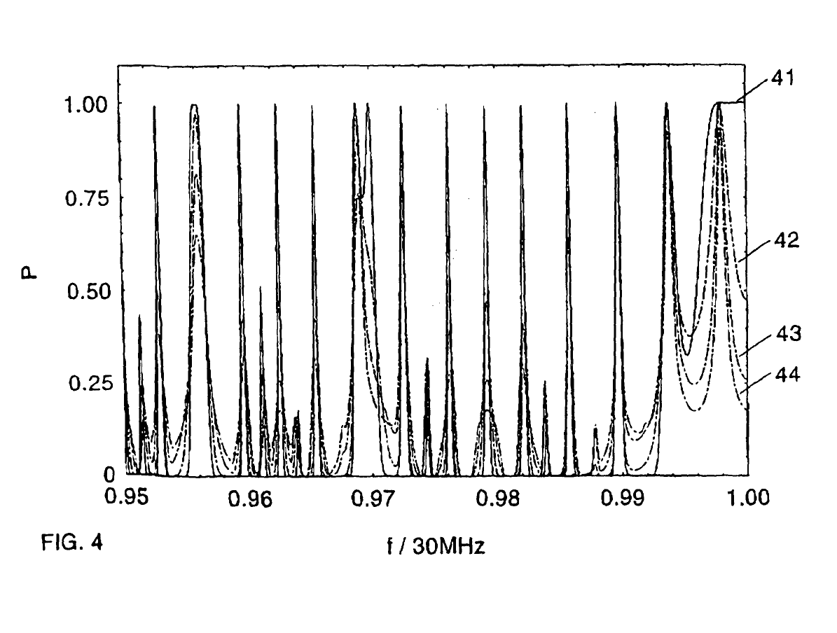

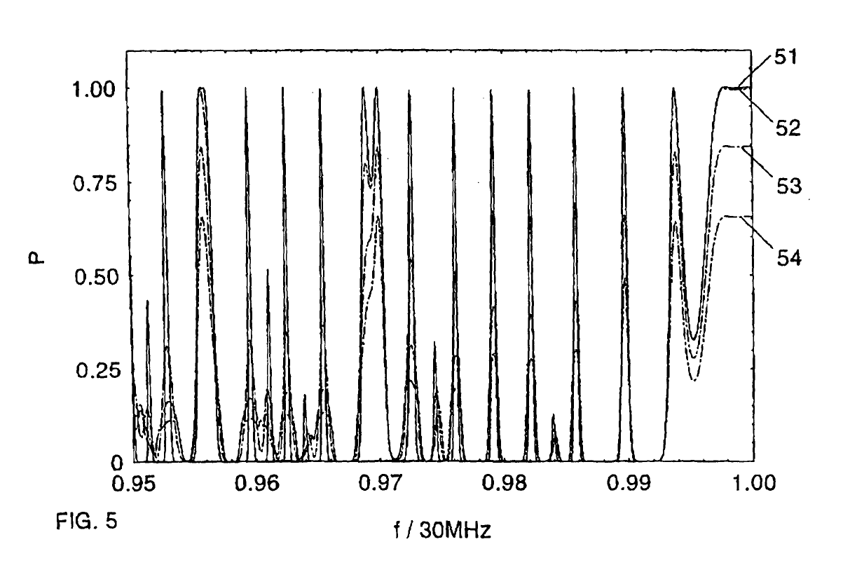

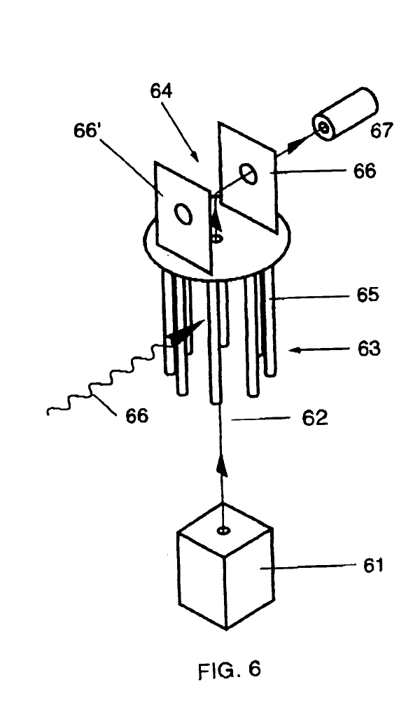

The oven 61 contains metallic Li and is typically heated to about 400° C. at which temperature the metal has melted and produced a vapor of free Li atoms. The atoms stream out of the oven 61 through a long pipe and form a vertical beam 62 moving at a speed of about 1 mm/μs. Appropriate potentials applied to a number of bars 65 of the Stark cage 63, for example eight bars as in the experiment, produce a homogeneous electric field which is felt by the Li-atoms when they are inside the Stark cage 63. The Li atoms are crossed within the Stark cage 63 by three laser beams 66 appropriately adjusted to selectively excite a single component of the Stark manifold of a single shell with principal quantum number n=25. The laser light is produced by three dye-lasers pumped by a single NdYAG-laser running at 14 Hz. The laser light 66 is on for about 5 nsec/shot. The excitation scheme is 2S→2p→3d→|n,n₁,n₂,m}=|25,24,0,0}, where n₁, n₂, and m are parabolic quantum numbers [11]. The final state is the highest-lying state the Stark spectrum. It is linear (ε=1) and its permanent electric dipole moment is antiparallel to the electric field. The field is quite strong at t=0 when the lasers are fired, 145 V/cm. This particular field-value was chosen to give the largest possible Stark splitting without appreciable inter-n mixing at the time of laser-excitation. FIG. 7 illustrates the electric field in the Stark cage. The lasers are fired at t=0 μs. The field decreases exponentially to zero in the interval from 1 to 5 μs. The rotating field is on in the interval from 9 to 13 μs. The Rydberg atoms, which are later selected for detection leave the Stark cage at about 30 μs. The constant magnetic field that we wish to measure is present while the electric field drops exponentially to zero. The variation is sufficiently slow that the response of the atoms is adiabatic. The Rydberg electron therefore remains in the uppermost energy level of the combined Stark-Zeeman spectrum, see FIG. 2, while it is slowly transformed from a linear Stark-state 23″, 24″at t=0 to a circular Zeeman-state 23, 24 at t≈5 μs. The wavefunction of the circular state is |n,l,m [symbol] =|25,24,24 [symbol] , where n, l, and m are spherical quantum numbers. This completes the description of the production and the preparation of the Rydberg atoms as probes for the magnetic field. 4.2 The Rotating Electric Field—The Basic Frequency of 30 MHz

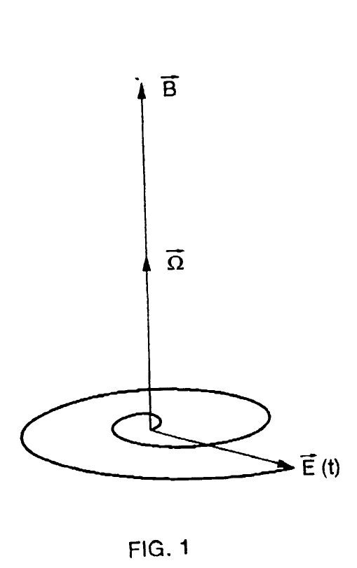

The rotating electric field, shown in FIG. 1 and already discussed in general terms in Sec. 2.3, is produced as follows. The eight bars of the Stark cage are coupled to the same sine-wave generator, but the signals are delivered to the individual bars through carefully adjusted lengths of cable to give progressively longer delays as one goes around the cage in the positive sense, anti-clockwise. The delay, Δtᵢ, for the i^{th} bar is Δtᵢ=i·Δt with i=1, . . . , 8. The basic delay Δt was adjusted such that f·Δt=1/8 at the frequency f₀=30 MHz. This is the basic frequency at which the potential of the i^{th} bar is Vᵢ=V₀cos(2πf₀t−iπ/4). Due to the phases iπ/4, the electric field from this potential distribution is homogeneous in a relatively large region near the symmetry axis of the Stark cage [12] and it rotates in the horizontal plane at 30 MHz.

After being turned on at t=t₀≈9 μs, see FIG. 7, the strength of the rotating electric field increases according to

E(t)=Eₘₐₓ·10^{-A·exp(-λ(t-t}^{₀}⁾⁾, (14)

where Eₘₐₓ, A, and λ are adjustable parameters. This functional dependence on time is realized by the use of a linear-in-dB amplifier controlled by appropriate electronic switches and an RC circuit of time constant 1/λ. The amplifier immediately follows the sine-wave generator, and from the amplifier the voltage is fed to the bars of the Stark cage through the delay-cables discussed above. In the present experiments we typically chose Eₘₐₓ=30 mV/cm, A=4, and 1/λ=2 μs. The time-dependence of E is characterized by a gentle onset from a low value, Eₘᵢₙ=3 μV/cm, at t=t₀, a fast rise when t−t₀≈0.5 μs, and a gentle approach towards the final value of 30 mV/cm at t−t₀≈1 μs. This value is held for a short period after which, from t=t₁, the field drops according to

E(t)=Eₘₐₓ·10^{A(exp(-λ(t-t}^{₁}⁾⁾⁻¹⁾ (15)

The drop is first rather sharp, but the rate of decrease diminishes fast so the field finally approches the initial low value, Eₘᵢₙ, very slowly. The non-adiabatic transitions that mark the desired balancing point, B_{eff}=0, may take place on either the leading edge of the pulse, Eq. (14), the trailing edge, Eq. (15), or on both.

4.3 Probing the Magnetic Field

With the explicit time-dependences given by Eqs.(14) and (15) we now discuss the responce of the atomic probes, the Rydberg atoms, to the rotating electric field for different values of B_{eff}. The question of adiabatic or non-adiabatic transformation is determined by the condition (9). For the present form of the rotating field it reads

$$\frac{λ}{2 πΔ f} ln \frac{{ω}_{max}}{2 πΔ f \cdot x} ⪡ \frac{{( 1 + {x}^{2} )}^{\frac{3}{2}}}{x} with {ω}_{max} = \frac{3 nh}{4 π me} {E}_{max} \qquad ( 16 )$$

at the rising edge of the pulse and

$$\frac{λ}{2 πΔ f} ln \frac{2 πΔ f \cdot x}{{ω}_{min}} ⪡ \frac{{( 1 + {x}^{2} )}^{\frac{3}{2}}}{x} with {ω}_{min} = \frac{3 nh}{4 π me} {E}_{min} \qquad ( 17 )$$

at the falling edge, where x=ω_{s/ω}_{L} measures the relative strengths of the electric and magnetic fields, and Δf=ω_{L}/2π is the detuning from the balance point B=(2m/e)Ω.

The common right-hand sides of (16) and (17) have a minimum near x=1 where they take the value 2√2. This and the slow variation of the logarithm for positive arguments justifies the following simplifications of (16) and (17), respectively,

$$Δ f ⪢ \frac{1}{4 π \sqrt{2}} \cdot λ \qquad ( 18 )$$

and

$$Δ f ⪢ \frac{A ln ( 10 ) - 1}{4 π \sqrt{2}} \cdot λ \qquad ( 19 )$$

Note, that (18) and (19) do not depend on the field amplitude, Eₘₐₓ. Of the two criteria (19) is the most restrictive. With the present values of the parameters it leads to a critical detuning of about 1 MHz. The transformation of the electronic state by the rotating field should therefore be strictly adiabatic and leave the Rydberg atoms in circular states when Δf is larger than 1 MHz, but the transformation is expected to change character near 1 MHz and become progressively more non-adiabatic as the detuning is decreased below this value. A strongly non-adiabatic transformation leaves the Rydberg atoms in a broad distribution of states.

4.4 Selective Field Ionization, SFI.

Most of the Rydberg atoms, see FIG. 6, have left the Stark cage 63 at 40 μs after the lasers were fired and find themselves in the region between the condenser plates 66, 66′. A ramped voltage rising from zero at a rate of 400 V/μs for about 8 μs is applied to the positive plate 66′ at t=46 μs. The negative plate 66 has a constant voltage of −5 V. The ramped voltage gives rise to a linearly increasing electric field between the plates 66, 66′. Rydberg atoms in a specific group of states break up and become ionized when the electric field reaches a certain critical value. This is the principle of the selective field ionization (SFI) mentioned earlier in the report. Once ionization has taken place, the ions are accelerated by the electric field and directed onto a detector 67. The resulting pulses from the detector 67 are recorded by an averaging digital oscilloscope which displays the pulses as a function of the time of ionization, or, since the ramp is linear in time, as a function of the field-strength that led to the ionization. After a fraction of a second, corresponding to only a few laser shots, a reasonably smooth spectrum is built up on the screen. This SFI-spectrum makes it possible to follow immediately in real time any change taking place with the Rydberg atoms when the various parameters of the experiment are adjusted. The most important parameter is the detuning, Δf which is controlled either directly by the rotation frequency, Ω, or indirectly by the strength of the external field, B.

4.5 The SFI-Spectra—Relative Strength R of the Adiabatic Peak

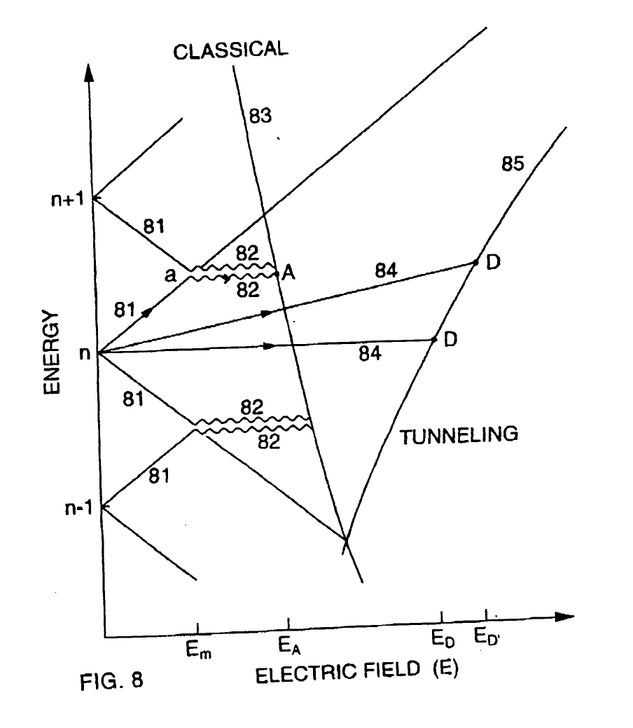

The field ionization proces is discussed with reference to FIG. 8 which in a schematic fashion shows energy levels for three shells n−1, n, and n+1 as a function of the electric field. Of the n² levels of each shell only a few are shown, including the extreme up- and down-shifted levels. The extreme levels of the individual shells meet at the field value, Eₘ. The behaviour of a given state for E>Eₘ depends on the projection, m, of the states' angular momentum on the direction of the electric field [13]. The extreme up- or down-shifted levels 81 correspond to linear states with m=0. The energy levels of these states show avoided crossings with levels from other shells in the region E>Eₘ. The levels are therefore indicated by the wiggly curves 82. At each avoided crossing, the involved states change character and as a result, the electron gradually moves closer to the point of classical field-ionization as E increases. The m=0 states 81, and neighboring states with m=±1, not shown, thus field ionize at the classical field-ionization limit 83. All other states with m=±2, ±3, . . . , ±(n−1) keep their character even when E>Eₘ and they field ionize at the quantal tunneling limit 85. The two different field ionization mechanisms 83, 85 are called adiabatic and diabatic, respectively. The point of adiabatic field ionization for a linear state is indicated by the letter A and the corresponding field by E_{A}, and the points of diabatic field ionization for two arbitrary non-linear states are indicated by the letter D and the corresponding fields by E_{D} and E_{D′}.

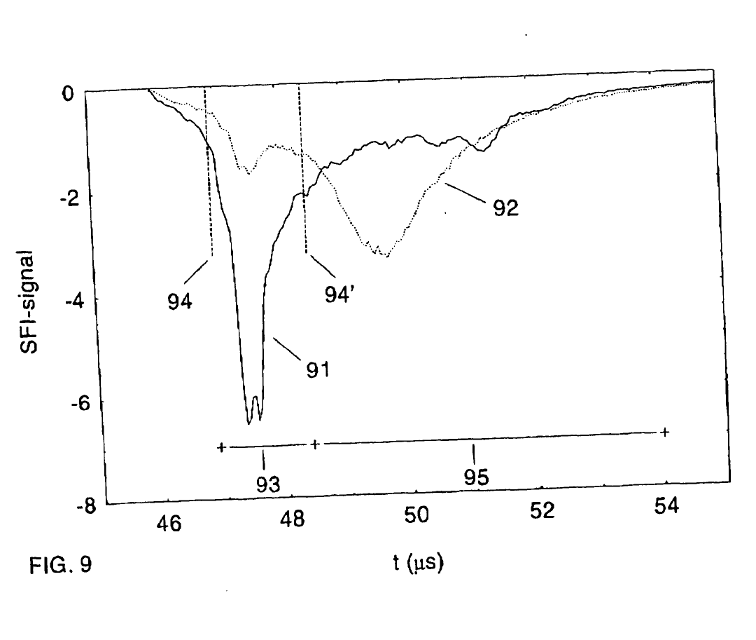

In a rising electric field, we thus expect the diabatic field ionization to occur at a later stage than the adiabatic field ionization. Representative SFI-spectra illustrating this are shown in FIG. 9.

The predominantly adiabatic SFI-spectrum 91 was obtained off resonance for a relatively large value of the detuning, i.e. 10% of the resonance frequency. The Rydberg atoms are therefore left in circular states when the rotating electric field is turned off, and as they fly out of the Stark cage and into the SFI-region they experience a slowly increasing electric field that adiabatically transforms them all into the same linear state. The ramp-field forces these states to follow the ionization path marked naA in FIG. 8. This leads to ionization at a relatively small value of the field strength, and a distinct peak in the SFI-spectrum at t=47.5 μs, only 1.5 μs after the onset of the ramped SFI voltage at t=46 μs.

The predominantly diabatic SFI-spectrum 92 of FIG. 9 was obtained on resonance. The Rydberg atoms are therefore left in a broad range of states when the rotating electric field is turned off. Most of these states have |m|>1. As they fly into the SFI-region the slowly increasing electric field may widen the distribution even further. The ramp-field forces states with |m|>1 to follow diabatic ionization paths like the two marked nD in FIG. 8. On the average, these Rydberg atoms are ionized at a large field strength corresponding to a long time interval. In the present example, they form a broad peak in the diabatic region 95 of the SFI-spectrum at about 50 μs, 4 μs after the onset of the ramped SFI voltage.

FIG. 9 clearly illustrates the dramatic variation of the SFI-spectrum that is seen when B_{eff}=B−(2m/e)Ω is tuned from a large value (adiabatic, curve 91) to a small value (diabatic, curve 92). An SFI-spectrum of good quality is obtained within a few seconds, so the resonance is easily found simply by observing the SFI-spectrum while tuning the current producing the magnetic field or the frequency of the sine-wave generator. The changing shape of the spectra was quantified simply by the relative strength, R, of the adiabatic peak. This is given by R=Aₐ/Aₜₒₜ, where Aₐ is the area within the adiabatic period 93 from the time 94 to the time 94′, and Aₜₒₜ is the total area of the SFI-spectrum corresponding to the adiabatic period 93 as well as the diabatic period 95. The parameter R is a measure of the adiabaticity of the transformation. Explicit expressions for the probability of having adiabatic transformation were introduced in Sec. 2.4.

4.6 The Resonance at 30 MHz

It is possible, in principle, to adjust the frequency of the homogeneous rotating field to match the magnetic field B. However, for reasons of simplicity, the Stark cage 63 was designed to produce a homogeneous rotating electric field only at the basic frequency of 30 MHz, Sec. 4.2. It was therefore necessary to tune through resonance at B−(2m/e)Ω=0 by varying the true magnetic field B while keeping the frequency fixed at Ω/2π=30 MHz. The field was varied by adjusting the current, I, running through the windings of the solenoid embracing the Stark cage.

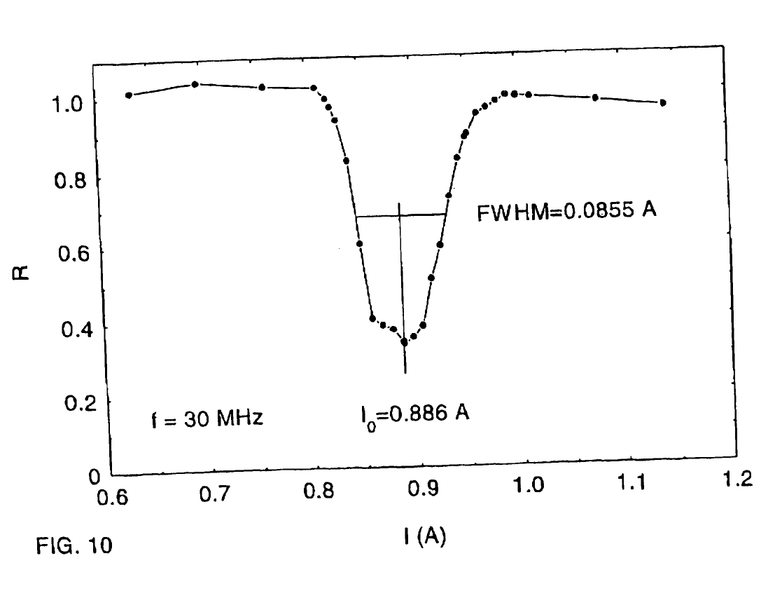

FIG. 10 shows the resonance as observed at 30 MHz. It agrees with expectations based on the discussion in Sec. 2.3 and in Sec. 4.3 above. When I is large or small compared to the resonance current of I₀=0.886 A the transformation by the rotating field is adiabatic and the adiabaticity parameter R is large, but it drops sharply when |I−I₀| is decreased below a critical value where the transformation becomes non-adiabatic. The full width at half maximum, FWHM, of the dip is less than 10% of I₀. On the frequency scale this corresponds to a FWHM of less than 3 MHz, which is in fairly good agreement with the estimated FWHM of about 1 MHz derived in Sec. 4.3 above. With a FWHM of less than 10%, the resonance frequency, and therefore B, can be determined to better than 1%.

The FWHM and the performance may be improved by selecting a smaller value of the parameter λ. This leads to a more gentle decline of the rotating field which will make the resonance structure even narrower and therefore determine I₀ with improved precision. The detailed shape of E(t) used in the present experiments is not unique, so one should also make an attempt to optimize the shape for better precision.

4.7 Resonances at Other Frequencies

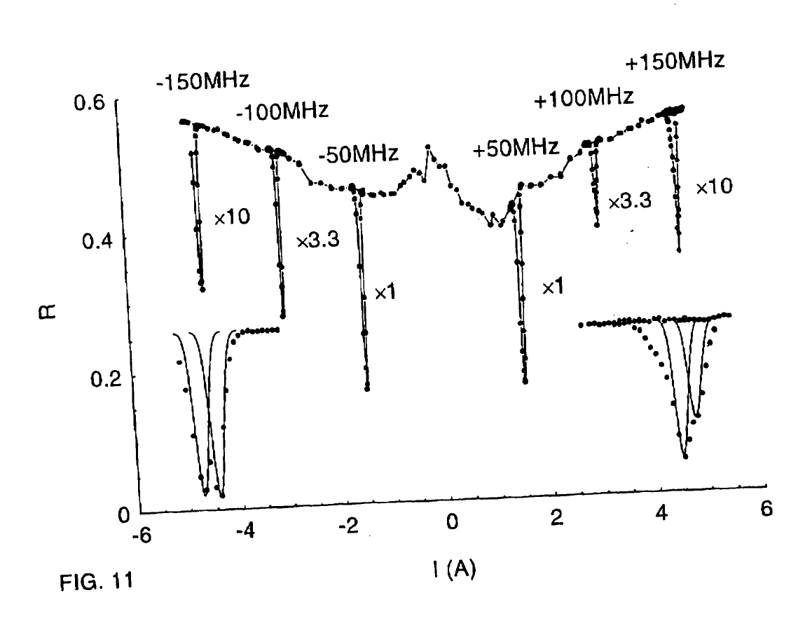

Since the experimental arrangement for the rotating field was designed to operate only at the basic frequency of 30 MHz it was at first somewhat surprising that clear resonances could be observed over a broad range of frequencies. Results obtained at f=50 MHz are shown in FIG. 11 to illustrate this point. The resonances at the currents ±1.51 A, ±3.02 A, and ±4.53 A resemble the resonance seen at f=30 MHz, and the current-to-frequency ratio of (0.886/30=0.0296) A/MHz found at 30 MHz shows that the three pairs of resonances at f=50 MHz correspond to frequencies of ±50 MHz, ±100 MHz, and ±150 MHz. The reason for the appearance of these resonances is simple. At the frequency f the potential of the i^{th} bar of the Stark cage is Vᵢ=V₀cos(2πft−iπ/4·f/f₀) where f₀=30 MHz and this potential distribution generally does not produce a homogeneous field rotating at a constant frequency inside the Stark cage. Instead, the amplitude and the rotation frequency depend on time and the instantaneous value varies from point to point. However, the field is everywhere periodic at the frequency f, so at each point the time-dependence can be expanded into a Fourier series. If the field vector is represented by a complex number, then the terms of the Fourier series have the form A^{±}ₚ·exp(±jp2πf), where j is the complex unit and p=0, 1, . . . , ∞. The ±-signs correspond to rotations in opposite directions. Since V₀ varies only slowly, the time-dependence of the potentials is quasi-harmonic, and all terms in the Fourier series except the two with p=1 therefore vanish. This explains the appearance in FIG. 11 of resonances at ±50 MHz. The resonances at ±100 MHz and ±150 MHz were at first seen only barely or not at all. However, when Eₘₐₓ was increased by a factor of 3.33, the resonances at ±100 MHz became clearly visible, and a further increasing by a factor of 3 brought the resonances at ±150 MHz out. The resonances at ±100 MHz and ±150 MHz are thus very weak relative to the ones at ±50 MHz, and since they are not observed for truly harmonic potentials, their presence is due to either the slow variation of V₀ or to experimental imperfections, perhaps a slight deviation from linearity of the instantaneous gain of the linear-in-dB amplifier at high voltage values.

The abscissa of FIG. 11 was expanded by a factor of 10 in limited regions around ±150 MHz to bring out more clearly the shapes of the resonances. Each resonance is clearly split in two. This is due to a small vertical E-field present in the Stark cage. Such splittings were occasionally seen at all frequencies, and they can be enforced or eliminated by appropriately biasing the top-plate of the Stark cage. The presence of a vertical E-field modifies the combined fields ω₁ and ω₂. The new values are ω₁=(ω_{L}+ωₛ^{v})eᵥ+ω_{S}eₕ and ω₂=(ω_{L}−ω_{S}^{v})eᵥ−ω_{S}eₕ, where eᵥ and eₕ are unit vectors in the vertical and horizontal directions, respectively. The resonance is now seen when ω=±ω_{S}^{v}. This shows that the resonance is shifted symmetrically up and down in frequency by the amount ω_{S}^{v}/2π. The splitting is thus symmetric and does not shift the centroid of the resonance structure. The relative FWHM of a single resolved dip is centroid of the resonance structure. The relative FWHM of a single resolved dip is 0.6%. Since the rise-time of the pulse is about 1 μs one expects a spread in the frequency of about 1 MHz during the transformation of the Rydberg states. This leads to the estimate FWHM≈1/150=0.7%, in fairly good agreement with the observation. The geometry of the setup allows the rise-time to be increased to at least 10 us corresponding to a thermal distance-of-flight of 10 mm. This should lower the FWHM by one order of magnitude.

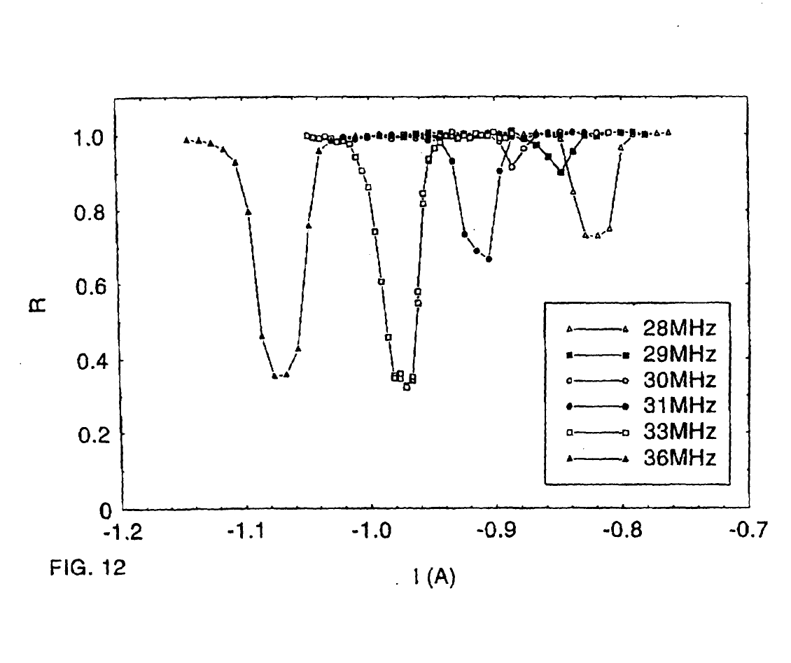

According to the analysis, only one Fourier component is present at the basic frequency of 30 MHz, where the electric field is homogeneous and rotates at a steady frequency. This was verified, as shown in FIG. 12, by the measurement of resonance curves at negative currents for a number of frequencies in the neighborhood of 30 MHz. As expected, the resonance becomes very weak and almost disappears near 30 MHz. A close inspection of FIG. 12 shows that the resonance is at its weakest close to 29.5 MHz instead of at 30 MHz, which was aimed for. The weakening of the resonance for negative currents shows that the technique is sensitive to the vector direction of the magnetic field.

4.8 Corrections

In going from Eq. (2) to Eq. (3) two terms quadratic in the small quantities Ω or B were ignored. The two terms are m/2·(Ω×r′)² and e/2·(Ω×r′)·(B×r). The first is independent of B and does not influence the balance of magnetic and fictitious forces, Eq. (5). The second depends on B, but it is very small. The ratio, σ, of this term to the B-dependent term in Eq. (2) is approximately σ=Ω·r/v, where Ω=2π·f≈2π·30×10⁶ c/s, r=n²·a₀≈625·0.53×10⁻¹⁰ m, and v=v₀/n≈2.18×10⁶/25 m/s, which leads to σ≈7×10⁻⁵. A term this small varying smoothly with B or Ω can only affect the balance, Eq. (5), very little, but the correction should be evaluated precisely by inclusion of the ignored terms in a proper theoretical description.

The conversion factor, B/f given in Sec. 2.2 applies for an electron bound by a fixed potential, or an infinitely heavy nucleus. For a finite nuclear mass, M, the electron isotope-dependent correction factors M/(M+m), which for ⁶Li and ⁷Li have values close to 1−9.1×10⁻⁵ and 1−7.8×10⁻⁵, respectively. These correction factors are known to a very good precision.

A time-dependent electric field can not exist without the presence of a magnetic field. In regions of vacuum, away from the sources of the electric field, the magnetic field is given by the appropriate boundary conditions and the Maxwell equations ∇·B=0 and ∇×B=1/c²∂E/∂t, where c is the velocity of light. The magnetic field can be calculated exactly. It vanishes on the symmetry axis of the Stark cage, and at the distance d from the axis the field is parallel to the axis and it oscillates with an amplitude of the order 2πfdE/c², which for d=2 mm, f=100 MHz, and E=1 V/cm is 4π/9·10⁻⁵ Gauss. Thus, apart from being exactly calculable the field is extremely small.

All materials used for constructing a gauge should be non-ferromagnetic. The magnetic susceptibilities of para- and diamagnetic materials useful for building a gauge are of the order of 10⁻⁵. Perturbations on the magnetic field of that order of magnitude must be considered.

An extremely small magnetic field is seen by the Li atoms due to their motion relative to the electric field (B_{⊥≅}10⁻⁸ Gauss for 1000 m/s og 1 V/cm). In the present embodiment the field is perpendicular to the electric field, the Li beam, and the external magnetic field. It is negligible.

4.9 Results and Discussion

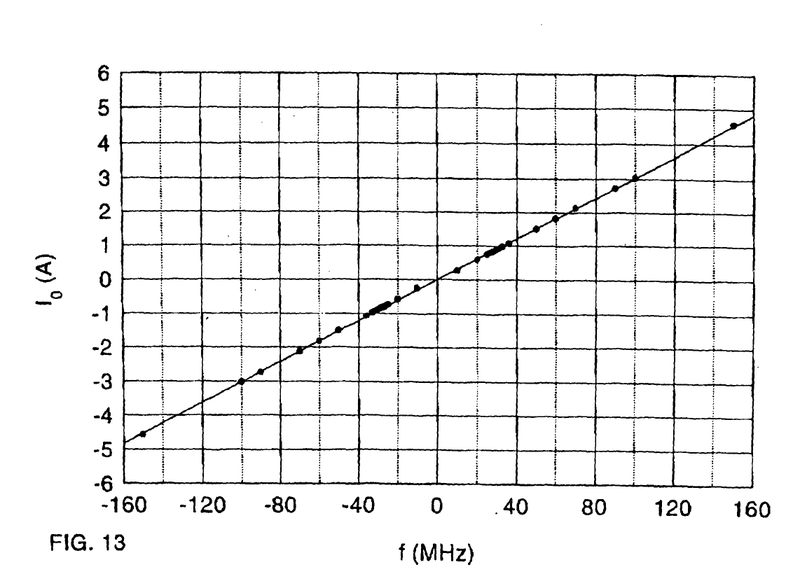

FIG. 13 shows the current at resonance, I₀, as a function of the imposed frequency, f. The data at ±50 MHz, ±100 MHz, and ±150 MHz were taken from FIG. 11. The experimental points all fall on a straight line through (0,0). I₀ is thus proportional to f as expected. The results are preliminary in the sense that no serious attempt has been made to optimize the experimental conditions. In spite of this, the data unambiguously show that magnetic fields can be measured precisely by the proposed new method.

The best resolution obtained so far is a relative FWHM of less than 1%. This corresponds to a precision on the position of the centroid of 0.1% or better. An improved theoretical understanding of the resonance phenomenon will help in finding the exact position of the resonance and in optimizing the shape of the leading and trailing edges of the rotating field for the best possible resolution. Eqs.(14) and (15) describe only a convenient practical example and do not represent an optimized choise. In a future application the harmonic waves applied to the bars of the Stark cage should be generated by digital rather than analogue techniques. This will facilitate the optimization of the pulse-shape and make it possible to use “correct” phase-shifts at all frequencies, i.e. homogeneous fields.

The data shown in FIG. 13 covers more than one decade in frequency corresponding to magnetic fields within the range [7-100] Gauss. This range can be extended both upwards and downwards. The upwards extension into the kGauss or Tesla regime will require the use of micro-wave fields in the region of a few GHz. In case the increased δ-value at high f, Sec. 4.8 above, gives rise to worry with respect to systematic errors, one can compensate by using smaller n-values, δ∝n³.

4.10 Alternative Embodiments

The results discussed above in Sec. 4.7 show that the atomic probes respond to the specific Fourier components present in the periodically varying electric field of the Stark cage. This can be used to simplify the method. The cage can be replaced by a less complex arrangement consisting of two vertical capacitor plates, one grounded and the other connected to a harmonic generator. This simplified system avoids the many precisely arranged bars of the Stark cage and it works equally well at all frequencies, but it will not be sensitive to the vector direction of the magnetic field—only the axis of the field. The non-rotating, but oscillating, electric field of the simplified arrangement can be perceived as a superposition of two rotating electric fields of equal magnitude. The two components of the oscillating field rotate in opposite directions at the same frequency as the oscillating field. If a magnetic field is in resonance with one of the rotating field components it will resonate with the other field component when its direction is reversed, and therefore the sensitivity to the vector direction of the field is lost.

Further simplification of the apparatus according to the invention is obtained if the pumped dye lasers are replaced by diode lasers. As compared to pumped dye lasers, modem diode lasers are small, they consume only little power, and are normally inexpensive. Diode lasers are readily available for two of the three transitions required in Li, 2s→2p at 671 nm and 3d→|25,24,0,0} at about 831 nm, but the third may require some prior developement due to the relatively short wavelength (2p→3d at 610 nm).

A disadvantage of using Li or other alkali atoms as atomic probes is the contamination by alkali atoms sticking to the surfaces of the cage. When reacting with molecules of the rest gas they tend to form thin insulating layers which may charge up and lead to spurious electric stray fields which in turn influence the performance of the apparatus as discussed in Sec. 4.7. A thermal beam of noble-gas atoms avoids these problems, but is more complicated to excite by lasers because of the large gab between the ground and the first excited states of these atoms. A beam of metastable He atoms with some fraction of metastables, He(2³S), excited by electron impact or UV-radiation is an attractive alternative.

4.11 Towards Ultra-High Precision

The possibility for a more radical improvement of the precision is offered by the quantum interference methods discussed in Sec. 2.4. The Ramsey method employing two rotating or oscillating fields separated in time by the period T is interesting in particular, because it leads to a pattern of fringes that depends only on the external magnetic field, the period T, and the rotation or oscillation frequency. However, when the rotating field is turned on and off suddenly, one also has Rabi oscillations, which interfere with the Ramsey fringes and tend to produce a very complicated spectrum, Eq. (12). In order to avoid this, a combination of the Ramsey method and the near-adiabatic transformation method described in Sec. 2.3. may be considered. Since the latter avoids the Rabi oscillations this should lead to a more transparent pattern of Ramsey fringes. Alternatively, some simplification of the Ramsey expression, Eq. (12), is obtained when ω_{R}·τ/2=i·π/2, where i is an integer. Simplification also obtains in the limit τ/T→0, where P_{Ramsey}=(ω_{S}·τ)²·cos(ω_{L}T/2)·[cos(ω_{L}T/2)−(ω_{L}τ)·sin(ω_{L}T/2)]. Due to the small value of T, P_{Ramsey} is always close to zero in this limit, and even more so when raised to a high power. The total probability for adiabatic transformation therefore reduces to P =P₊=(1−P_{Ramsey})²ⁿ⁻². It is close to zero except near P_{Ramsey}=0, where it rises to unity. This happens in the close vicinity of ω_{L}T/2=π/2±iπ. Every peak in P thus constitutes a measurement of the external field B. If Ωᵢ=2πfᵢ is the frequency of the i^{th} peak then 2m/e·Ωᵢ=B−2m/e·(1±2i)π/T with the appropriate numbering of the peaks. The method has two parameters, B and T, which are both determined accurately when many well resolved fringes are observed.

The sharpness of the Ramsey fringes increases when the interval T between the two interactions with the oscillating or rotating field is increased. In the present experimental arrangement, or in any other single-pass arrangement with a hot thermal beam, this interval can not be made very much longer than 10 μs corresponding to a flight path of the order of 10 mm. However, the interval could be much longer if a so-called atomic fountain were used as in the most advanced version of the atomic clock [14]. Very shortly, atomic fountains are realized as follows. An ensemble of atoms is first cooled and trapped by lasers. At a certain time the trapping lasers are turned off in such a way that the atoms get a small kick in the upwards direction as they are turned loose. Gravity subsequently decreases the upwards velocity until the atoms stop at the top of the fountain and then fall, just like the water in a garden fountain. With this technique, the atoms can be made available for experimentation during periods of the order of several msecs (≈0.005 sec), which is of the order of the natural lifetime of circular atoms of principal quantum number n in the interval 25-40, and within this period the atoms move only very little, one mm or less. This technique has the distinct advantage of combining the highest precision with a small measuring volume. A Zeeman slower can replace the atomic fountain [15].

### 5. CONCLUSION

Theoretical considerations and experimental results have demonstrated that magnetic fields may be measured directly in units of frequency by the ApSR method and that the conversion factor linking the unit of frequency to the unit of magnetic field is the well-known constant-of-nature e/2m, the Bohr magneton divided by Plancks constant. An important virtue of the method is this absence of system-dependent parameters which makes the method absolutely reliable and free of any kind of drift. Resonances of FWHM=0.6% were obtained in a pilot experiment with the near-adiabatic transformation method under circumstances for which a simple estimate led to the expectation FWHM=0.7%. This corresponds to a precision on the magnetic field of 0.06%. The precision can be increased by at least a factor of 10 with the present setup and the near-adiabatic transformation method. Two quantum interference methods hold the potential for considerably improving the precision beyond what has already been achieved. When combined with the most precise of the two methods, the Ramsey method, the ApSR technique may prove to be the ultimate for magnetic field measurements. This configuration is thus a preferred method.

### 6. REFERENCES

[1] N. Calder, The manic sun, Pilkington Press (1997).

[2] L. D. Landau and E. M. Lifshitz, Mechanics, Pergamon Press (1976).

[3] L. D. Landau and E. M. Lifshitz, The Classical Theory of Fields, Pergamon Press (1975).

[4] National Institute of Standards and Technology (USA), http://physics.nist.gov/.

[5] A. K. Kazansky and V. N. Ostrovsky, J. Phys. B: At. Mol. Opt. Phys. 29, L855 (1996).

[6] J. Hare, M. Gross, and P. Goy, Phys.Rev.Letters 61, 1938 (1988).

[7] L. Kristensen, E. Horsdal-Pedersen, and P. Sørensen, J. Phys. B: At. Mol. Opt. Phys. 31, 1049 (1998).

P. Sørensen, J. C. Day, B. D. DePaola, T. Ehrenreich, E. Horsdal-Pedersen, and L. Kristensen, J. Phys. B: At. Mol. Opt. Phys. 32, 1207 (1999).

L. Kristensen, T. Bove, B. D. DePaola, T. Ehrenreich, E. Horsdal-Pedersen, and O. E. Povlsen, J. Phys. B: At. Mol. Opt. Phys. 33, 1103 (2000).

[8] A. Bommier, D. Delande, and J. C. Gay, Atoms in Strong Fields, edited by C. A. Nicolaides et al. (Plenum, New York, 1990) p 155.

[9] N. F. Ramsey, Nuclear Moments, John Wiley and Sons (1953).

[10] L. Allen and J. H. Eberly, Optical resonances and two-level atoms, Dover Publi cations, N.Y. (1987).

[11] L. D. Landau and E. M. Lifshitz, Quantum Mechanics, Pergamon Press (1965).

[12] J. L. Horn, D. M. Homan, C. S. Hwang, W. L. Fugua III, and K. B. MacAdam, Rev. Sci. Instrum. 69, 4086 (1998).

[13] T. F. Gallagher, Rydberg Atoms, Cambridge University Press, (1994).

[14] C. Fertig and K. Gibble, Phys. Rev. Letters, 85, 1622 (2000).

[15] W. D. Phillips, J. V. Prodan, and H. J. Metcalf, Progress in Quantum Electronics 8, 119 (1984)

### 7. LIST OF SYMBOLS

ApSR acronym for atomic pseudo-spin resonance.

A gain constant

A magnetic vector potential.

a Pauli-Runge-Lenz operator.

a₀ Bohr radius of the ground state of hydrogen.

\vec{B}, B magnetic field vector.

B strength of magnetic field.

\vec{B}_{eff}, B_{eff} effective magnetic field vector.

\vec{E}, E electric field vector.

E strength of electric field.

Eₘₐₓ, Eₘᵢₙ maximum and minimum value of rotating electric field.

E_{A}, E_{D} electric field at adiabatic and diabatic field ionization.

e elementary charge.

c velocity of light in vacuum.

d distance from symmetry axis of Stark cage.

f frequency.

f₀ frequency at resonance

FWHM acronym for full width at half maximum.

h Plancks constant.

H, Hₐ Hamilton operator.

I current.

I₀ current at resonance.

\vec{j}₁, j₁ pseudo-spin operator 1.

\vec{j}₂, j₂ pseudo-spin operator 2.

j₁=j₂=j size of pseudo-spins.

L Lagrange function.

l electron angular momentum operator.

M mass of nucleus.

m mass of electron.

mⱼ₁ projection of pseudo-spin 1.

mⱼ₂ projection of pseudo-spin 2.

n principal quantum number.

NMR acronym for nuclear magnetic resonance.

P_{Rabi} Rabi probability for spin flip.

P_{Ramsey} Ramsey probability for spin flip.

P_{R} Rabi or Ramsey probability for spin flip.

P₊probability for adiabatic mixing.

P₋probability for diabatic mixing.

P probability.

\vec{P}′, p′ vector momentum of electron relative to nucleus in rotating system.

R relative strength of adiabatic peak of SFI-spectrum.

t time parameter.

\vec{r}, r vector position of electron relative to nucleus in inertial system.

r distance to electron from nucleus in inertial system.

\vec{r}′, r′ vector position of electron relative to nucleus in rotating system.

r′ distance to electron from nucleus in rotating system.

s electron spin operator.

SFI acronym for selective field ionization.

SQUID acronym for superconducting quantum interference device.

T period between pulses.

V electrostatic potential of nucleus. system.

∇ Laplace operator.

Δf detuning from resonance.

δ ratio of two terms of Eq. (2)

ε eccentricity.

λ reciprocal RC time-constant.

\vec{v}, v vector velocity of electron relative to nucleus in inertial system.

v speed of electron relative to nucleus in inertial system.

\vec{v}′, v′ vector velocity of electron relative to nucleus in rotating system.

v′ speed of electron relative to nucleus in rotating system.

v₀ Bohr velocity of the ground state of hydrogen.

σ width of time-distribution.

τ duration of pulse.

\vec{Ω},Ω rotation vector.

ω_{L} Larmor frequency.

ω_{S} Stark frequency.

\vec{ω}₁, ω₁ combined Stark and Larinor frequencies.

ω₁ size of combined Stark and Larmor frequencies.

\vec{ω}₂, ω₂ combined Stark and Larmor frequencies.

ω₂ size of combined Stark and Larmor frequencies.

ω, ω_{R} Stark-Zeeman—or Rabi frequency.

1. Method for m the absolute strength of a magnetic field by relating said strength B of said magnetic field to the frequency Ω of a periodically varying electric field, characterised by providing an atomic probe with Rydberg electrons in at least one highly cited state, said magnetic field and acting of said periodically varying electric field with frequency Ω on said atomic probe, said electric field not being parallel with the magnetic field B, and balancing the magnetic field B with the frequency Ω of the electric field to satisfy B=(2m/e)Ω.

2. Method according to claim 1, characterised in that the electric field is perpendicular to the magnetic field.

3. Method according to clams 1 or 2, characterised in that said at least one highly exited state is obtained by laser excitation of said atoms.

4. Method accoding to claim 3, characterised in that said laser excitation is obtained with triple excitation of said atoms by three laser beams.

5. Method according to claims 1-4, characterised in that said laser excited atoms are exposed to a decreasing linear electric field prior to said periodically varying electric field.

6. Method according to caimns 1-5, characterised in that said method comprises determining the relative number of adiabatically ionised atoms.

7. Method according to claim 6, characteried in that said method further comprises time resolved detection of ionised atoms from said atomic probe after exposure of said atoms to said periodically varying electric field.

8. Method acccording to claim 7, characterised in that said detecting of said ionised atoms comprises field ionisation.

9. Method according to claims 1-8, characterised in that said atomic probe is a stream of Lithium atoms.

10. Apparatus adapted to perform the method according to claim 1-9 characterised by an atomic probe in a magnetic field with Rydberg electrons in at least one highly excited state, an electric field generator for generation of a periodically varying electric field with determined frequency acting on said atomic probe, and a detector arrangement for determination of the relative number of adiabatically ionised atoms from said atomic probe.

11. Apparatus according to claim 10, characterised in that said atomic probe comprises a stream of atoms wherein said atoms are excited by laser excitation.

12. Apparatus according to clam 10 or 11 characterised in that said electric field generator comprises a stark cage with a plurality of bars.

13. Apparatus according to claims 10-12 characterised in that said apparatus further comprises a linear electric field generator for applying a linear electric field on said atomic probe prior to said periodically varying electric field.

14. Apparatus according to claims 10-13 characterised in that said detector arrangement comprises electrodes for field ionisation of said atoms and a detector for detecting said field ionised atoms.

15. Apparatus according to claims 10-14 characterised in that said atoms are Lithium atoms.

16. Use of a method according to claims 1-9 for calibration of magnetic probes.
